(19) United States
(12) Patent Application Publication
(10) Pub. No.: US 2024/0012972 A1
(43) Pub. Date: Jan. 11, 2024

(54) Techniques For Assessing Health Of Configurable Logic Circuits

(71) Applicant: Intel Corporation, Santa Clara, CA (US)

(72) Inventors: Michael Neve De Mevergnies, Guidel (FR); Geoffrey Strongin, Tigard, OR (US)

(73) Assignee: Intel Corporation, Santa Clara, CA (US)

(21) Appl. No.: 18/475,199

(22) Filed: Sep. 26, 2023

(51) Int. Cl. G06F 30/34

(52) U.S. Cl. CPC G06F 30/34

(57) ABSTRACT

An integrated circuit includes a region of configurable logic circuits and a configuration controller circuit that generates a first health condition report indicating a first health condition of the region before configuring the configurable logic circuits according to a circuit design. The configuration controller circuit generates a second health condition report indicating a second health condition of the region after configuring the configurable logic circuits according to the circuit design.

### TECHNICAL FIELD

The present disclosure relates to electronic integrated circuit devices, and more particularly, to techniques for assessing the health of configurable logic circuits in an integrated circuit.

### BACKGROUND

Configurable integrated circuits can be configured by users to implement desired custom logic functions. In a typical scenario, a logic designer uses computer-aided design (CAD) tools to design a custom circuit design. When the design process is complete, the computer-aided design tools generate configuration data. The configuration data is then loaded into configuration memory elements that configure configurable logic circuits in the integrated circuit to perform the functions of the custom circuit design. Configurable logic integrated circuits can be used for co-processing in big-data or fast-data applications. For example, configurable logic integrated circuits may be used in application acceleration tasks in a datacenter and may be reprogrammed during datacenter operation to perform different tasks.

### BRIEF DESCRIPTION OF DRAWINGS

FIG. 1 is a diagram that shows a configurable integrated circuit (IC) that can be used with techniques disclosed herein.

FIG. 2 is a diagram of a flow chart that illustrates examples of operations that can be performed to assess the health of a region of configurable logic circuits in a configurable IC before and after the region has been configured according to a circuit design.

FIG. 3 is a diagram of an illustrative configurable integrated circuit (IC) that can be configured according to a user circuit design as disclosed herein with respect to FIGS. 1-2.

FIG. 4 is a diagram of another illustrative example of a configurable integrated circuit (IC) that can include examples disclosed herein.

FIG. 5 is a diagram of a circuit design system that can be used to design integrated circuits in accordance with an embodiment.

FIG. 6 is a diagram of illustrative computer-aided design (CAD) tools that can be used in a circuit design system in accordance with an embodiment.

### DETAILED DESCRIPTION

In some applications of configurable integrated circuits (ICs), a cloud service provider (CSP) rents out allocations of configurable logic circuits in a single configurable integrated circuit (IC) to multiple customers. Configurable ICs are often designed to allow customers to configure their circuit designs to process workloads, without the burden of equipment management. A CSP can rent out regions of configurable logic circuits in a configurable IC to multiple customers so that the customers can load their own configuration data for sensitive or proprietary circuit designs into the rented regions of the configurable IC.

Renting out regions of configurable logic circuits in a single configurable IC to multiple customers (i.e., tenants) increase utilization of resources. In order to provide a cost effective solution, the CSP resets the rented regions of configurable logic circuits and allows the same configurable logic regions to be reused by different tenants.

Confidential computing enables tenants to program a region of configurable logic circuits of a configurable IC with a circuit design, while guaranteeing the confidentiality of the circuit design from the cloud service provider (CSP) that owns the configurable IC. An example of a sensitive circuit design is an artificial neural network (ANN) that extracts high value analytic insights on large data. The tenant keeps the circuit design for the ANN secret by ensuring that the circuit design cannot be decrypted, copied, or stolen by a competitor or by the CSP.

However, a circuit design may contain specific configurations for the configurable logic circuits that could damage the configurable IC (e.g., by simultaneously forcing a logic 0 and a logic 1 on a routing line, bypassing one-hot encoding configuration, etc.) or accelerate the degradation of the configurable IC (e.g., forcing a hot spot, concentrating ring-oscillators in a small regions, etc.). Because a circuit design is generated by the tenant and is encrypted, the CSP cannot check that the circuit design complies with all of the design rules expected for the configurable IC. Tenants (or malicious actors) could damage the configurable IC by accident (or on purpose), and the CSP may find it difficult to determine the cause of a failure or degradation, or to prove that the damage was linked to the circuit design created by the tenant.

According to some examples disclosed herein, a configurable IC generates health reports of a region of configurable logic circuits in the configurable IC that are configured by a tenant of the region. The configurable IC generates a first health report of the region before the region is configured according to a circuit design generated by the tenant. The configurable IC generates a second health report of the region after the region has been de-configured from the circuit design, and the tenant has relinquished the region. The first and second health reports of the region are then compared. Any difference between the two health reports may indicate damage or degradation caused by the circuit design under the rental period, without comprising the confidentiality of the circuit design.

With this solution, the CSP can detect any damage or degradation to the configurable IC, without deterring potential tenants that are concerned about protecting the confidentiality of their circuit designs. The circuit design does not have to undergo an audit process from a third party. Also, the tenant can get a clear picture of the current condition of the configurable IC that will host a circuit design. The techniques disclosed herein can be used to assess the health of a configurable IC with cryptographic properties to assure fair play between the tenant of the configurable IC and the owner of the configurable IC.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs). As discussed herein, an integrated circuit (IC) can include hard logic and/or soft logic. As used herein, “hard logic” generally refers to circuits in an integrated circuit device that are not configurable by an end user. The circuits in an integrated circuit device (e.g., in a configurable logic IC) that are configurable by the end user are referred to as “soft logic.”

Configurable integrated circuits (ICs), such as field programmable gate arrays (FPGAs), integrate a variety of test features that screen for defects during high volume manufacturing and in production. The test features can include redundancy options to correct the defects and increase yield. According to some examples disclosed herein, a configuration controller circuit in a configurable IC accesses the test features of a region of the configurable IC and runs pre-established test patterns to assess the current health condition of the region. The results of the test patterns are aggregated in a health report that includes the results along with a cryptographic signature to attest the authenticity of the report. The attestation allows an owner of the configurable IC and a tenant of the region to use the health report to prove the condition of the configurable IC when the health report was created. Along with the results of the test patterns, the attestation can include a timestamp, a unique identifier of the configurable IC, a public key of a reporting service for the configurable IC, the region of the configurable IC, and any other information used for attesting to the authenticity of the health report.

The reporting service covers the entirety of the configurable soft logic circuits in the configurable IC or a region (i.e., a subset) of the configurable soft logic circuits in the configurable IC if partial reconfiguration (PR) is used. In the case of PR, the owner of the configurable IC (e.g., the CSP) indicates to the configuration controller circuit which PR region in the configurable IC is to be analyzed. The tenant then creates a circuit design against a specific PR region of the configurable IC. The signature process ties the circuit design created by the tenant to the specific PR region of the configurable IC, so that the correspondence between the intended PR region and the health report can be unequivocally established.

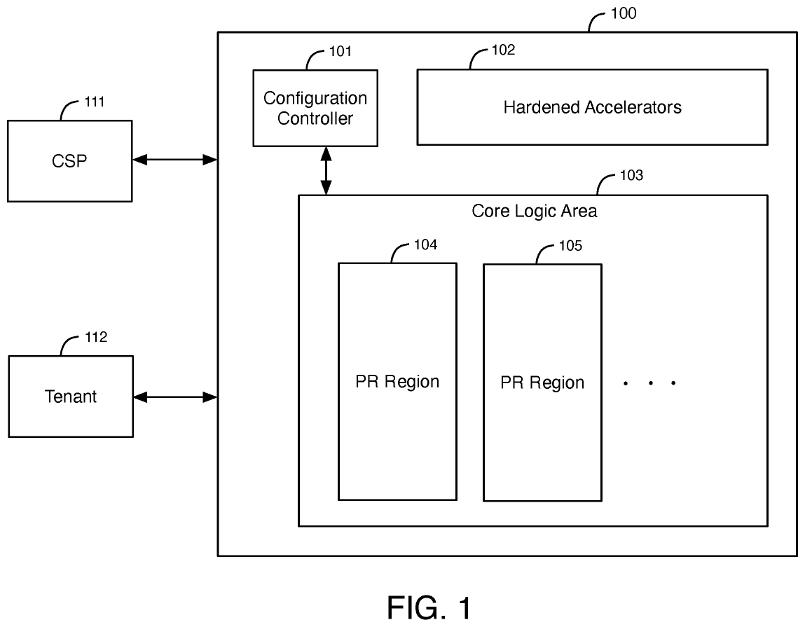

FIG. 1 is a diagram that illustrates a configurable integrated circuit (IC) 100 that can be used with techniques disclosed herein. Configurable IC 100 includes a configuration controller circuit 101, hardened accelerator circuits 102, and a core logic area 103. Core logic area 103 includes multiple regions of configurable logic circuits (soft logic), including regions 104 and 105. Each of the regions 104 and 105 includes several configurable logic circuits. The arrangement of regions 104-105 shown in FIG. 1 is merely an example. In other implementations, the regions of configurable logic circuits can be arranged in any fashion, for example, in an array of rows and columns. FIG. 1 also illustrates a cloud service provider (CSP) 111 that owns the configurable IC 100 and a tenant 112 of one or more of the regions of configurable logic circuits in core logic area 103.

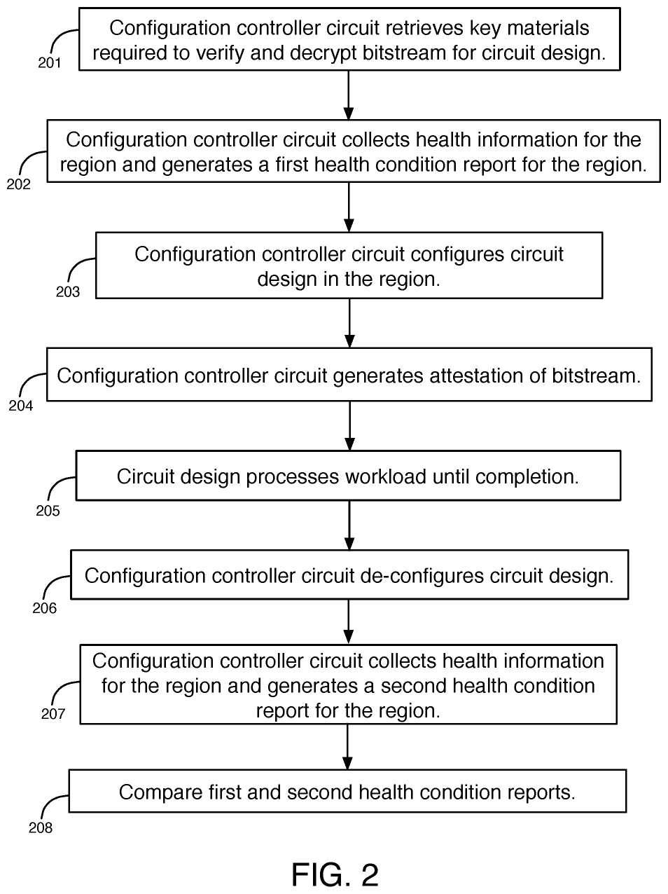

FIG. 2 is a diagram of a flow chart that illustrates examples of operations that can be performed to assess the health of a region of configurable logic circuits in a configurable IC before and after the region has been configured according to a circuit design. The operations of FIG. 2 are disclosed herein in the context of FIG. 1 as an example. In this context, a CSP 111 owns the configurable IC 100 and rents a region of IC 100 to tenant 112. Also, the regions of configurable logic circuits (e.g., regions 104-105) in core logic area 103 are partial reconfiguration (PR) regions in the example of FIG. 2.

Initially, the CSP 111 advertises the regions of configurable IC 100 (e.g., in a cloud FPGA infrastructure). The regions of core logic region 103 are defined by profiles containing the compute and acceleration capacity of the regions that are available to a tenant. The capacity of each region as defined in one of the profiles can, for example, include the number of logic elements, the sizes of memory circuits (e.g., random access memory or RAM), access to offload cryptographic accelerators, access to hardened processor cores, access to protected memory regions, access to services of the configuration controller circuit 101 (e.g., security functions), and access to input/output circuits of IC 100 (e.g., Peripheral Component Interconnect Express (PCIe), Ethernet, etc.).

The tenant then selects one of the regions (e.g., region 104 or 105) based on the profile for that region meeting the requirements of a circuit design that the tenant intends to configure in the configurable IC owned by the CSP. The tenant then compiles the circuit design against the selected region to generate a bitstream that represents the circuit design. The tenant then signs and encrypts the bitstream. The protected bitstream is then sent to the CSP. The CSP then schedules the protected bitstream on the selected region.

In operation 201 shown in FIG. 2, the configuration controller circuit 101 then establishes a secure session with the tenant to retrieve key materials required to verify and decrypt the protected bitstream for the circuit design. The CSP then requests the configuration controller circuit 101 to generate a health condition report of the selected region of the configurable IC 100. In operation 202, the configuration controller circuit 101 collects health information for the selected region and generates a first health condition report (HCR) that includes the health information for the selected region. The health information for the selected region included in the first HCR can include, for example, results of tests of the configurable logic circuits and the configurable routing in the selected region. The tests can be performed, for example, by providing test patterns to the configurable logic circuits and the configurable routing in the selected region and comparing values received back from the configurable logic circuits and the configurable routing in the selected region to expected values to generate the results of the tests. As another example, the tests can also, or alternatively, use testing techniques that are typically used in the pre-production and testing phases of IC manufacturing to augment the scope of the HCR.

The configuration controller circuit 101 then signs the first HCR for attestation and non-repudiation purposes and generates a timestamp for the first HCR that indicates when the first HCR was generated. The attestation for the first HCR can include the timestamp, a unique identifier of the configurable IC 100, a public key of a reporting service for the configurable IC 100, the selected region of the configurable IC 100, and any other information used for attesting to the authenticity of the first HCR. The configuration controller circuit 101 then provides the first HCR to the CSP 111. The CSP 111 can save the first HCR in a log and share a copy of the first HCR with the tenant 112.

The tenant 112 can verify the health of the selected region of the configurable IC 100 before configuring the circuit design in the selected region. The tenant 112 can check the health of the selected region by evaluating the health information in the first HCR and the timestamp of the first HCR. If the first HCR indicates that the selected region has adequate health information, then the tenant 112 confirms receiving a legitimate health condition report for the selected region to the CSP 111.

In operation 203, the configuration controller circuit 101 configures the circuit design of the tenant in the selected region of configurable logic circuits in the configurable IC 100. For example, the configuration controller circuit 101 can transmit the decrypted bitstream for the circuit design to the selected region to be stored in configuration RAM (CRAM) in the selected region for configuring the configurable logic circuits in the selected region.

In operation 204, the configuration controller circuit 101 generates an attestation (e.g., a tenant bitstream configuration attestation or TBCA) of the bitstream for the circuit design being used to configure the configurable logic circuits in the selected region of the configurable IC 100. In operation 205, the circuit design in the selected region of the configurable IC 100 processes the workload of the circuit design, until the completion of the workload. Then, the circuit design notifies the CSP that the workload has completed. In operation 206, the configuration controller circuit 101 de-configures the circuit design from the selected region of the configurable IC 100 in response to input from the CSP after the workload has completed. As an example, the configuration controller circuit 101 can zeroize the CRAM in the selected region to de-configure the circuit design from the selected region.

Then, the CSP requests the configuration controller circuit 101 to generate a second health condition report (HCR-2) for the selected region of the configurable IC. In operation 207, the configuration controller circuit 101 collects health information for the selected region and generates the second health condition report (HCR-2) that includes the health information for the selected region after the circuit design has been de-configured from the selected region. The health condition reports generated in operations 202 and 207 are for the same selected region of configurable logic circuits in the IC 100. The health information for the selected region in the second HCR-2 can include, for example, results of additional tests of the configurable logic circuits and the configurable routing in the selected region. The additional tests can be the same types of tests as, or similar to, the first tests conducted in operation 202 and discussed above.

The configuration controller circuit 101 then signs the second HCR-2 for attestation and non-repudiation purposes and generates a second timestamp for the second HCR-2 that indicates when the second HCR-2 was generated. The attestation for the second HCR-2 can include the second timestamp, the unique identifier of the configurable IC 100, the public key of the reporting service for the configurable IC 100, the selected region of the configurable IC 100, and any other information used for attesting to the authenticity of the second HCR-2.

The second health condition report (HCR-2) can then be provided to the CSP 111 and shared with the tenant 112. In operation 208, the first health condition report (HCR) is compared to the second health condition report (HCR-2) to determine if any damage or degradation occurred to the selected region of the configurable IC during the rental period of time between the two timestamps. Operation 208 can, as examples, be performed by the configuration controller circuit 101, by the CSP 111, and/or by the tenant 112. If HCR and HCR-2 present significant differences in health information above the terms agreed upon between CSP 111 and tenant 112 prior to renting the selected region (e.g., as stated in a user agreement or contract), the CSP 111 can rely on the HCR, the HCR-2, and the TBCA to prove that any damage to, or degradation of, the selected region was caused by the tenant's circuit design. On the other hand, if the HCR and HCR-2 indicate similar health information, the tenant can prove that its circuit design did not cause damage to, or degradation of, the selected region of the configurable IC.

The operations disclosed herein with respect to FIG. 2 can provide a service to the CSP to assess the health condition of the configurable IC that is attestable. The first health condition report can be used to securely record the condition of a region of the configurable IC, before a tenant configures its confidential circuit design on the region of the configurable IC. A second health condition report of the same region documents any damage or degradation that could have been caused by the circuit design of the tenant. The operations discussed above provide a value-add feature that reduces barriers for adoption of confidential computing on configurable ICs in CSPs.

In alternative implementations, the operations disclosed herein with respect to FIG. 2 can support the transfer of ownership of a configurable IC. The operations of FIG. 2 can be used to generate a report of health condition, so that a prospective buyer of the configurable IC knows exactly the health of the configurable IC. The report can include other information useful to the buyer, such as the number of In-Field-Programmable fuses left, the number of previous buyers, etc.

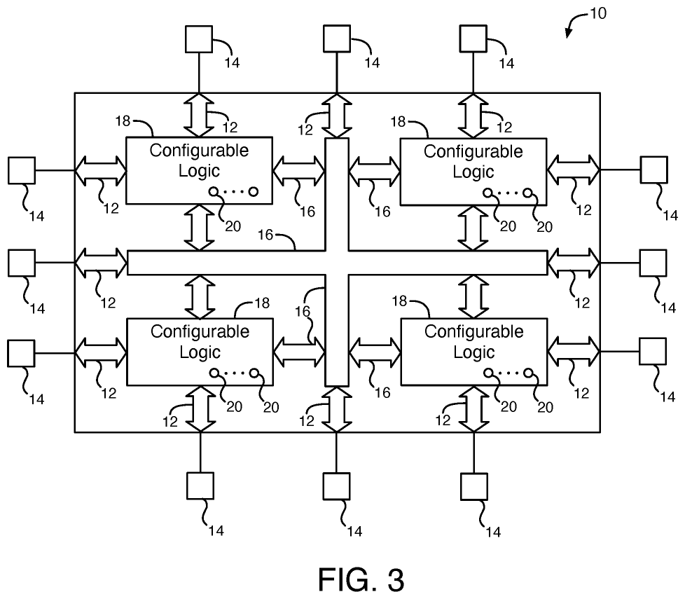

FIG. 3 is a diagram of an illustrative configurable logic integrated circuit (IC) 10 that can be configured according to a user circuit design as disclosed herein with respect to FIGS. 1-2. Configurable logic IC 10 is an example of an IC as disclosed herein, such as IC 100. As shown in FIG. 3, configurable logic integrated circuit 10 can have input-output circuitry 12 for driving signals off of IC 10 and for receiving signals from other devices via input-output pads 14. Interconnection routing resources 16 such as global, regional, and local vertical and horizontal conductive lines and buses may be used to route signals on IC 10. Interconnection resources 16 include fixed interconnects (conductive lines) and programmable interconnects (i.e., programmable connections between respective fixed interconnects). IC 10 includes regions of configurable logic circuitry 18 that can be partial reconfiguration regions used for tenant circuit designs, as disclosed herein with respect to FIGS. 1-2. Configurable logic circuitry 18 may include combinational and sequential logic circuitry. Configurable logic circuitry 18 may be configured to perform custom logic functions.

Configurable logic IC 10 contains memory elements 20 that can be loaded with configuration data using pads 14 and input-output circuitry 12. Once loaded, the memory elements 20 may each provide a corresponding static control output signal that controls the state of an associated logic component in configurable logic circuitry 18. Typically, the memory element output signals are used to control the gates of field-effect transistors. In the context of configurable integrated circuits, the memory elements 20 store configuration data and are sometimes referred to as configuration random-access memory (CRAM) cells. The configuration data programs the configurable logic 18 to perform the custom logic functions according to the circuit design.

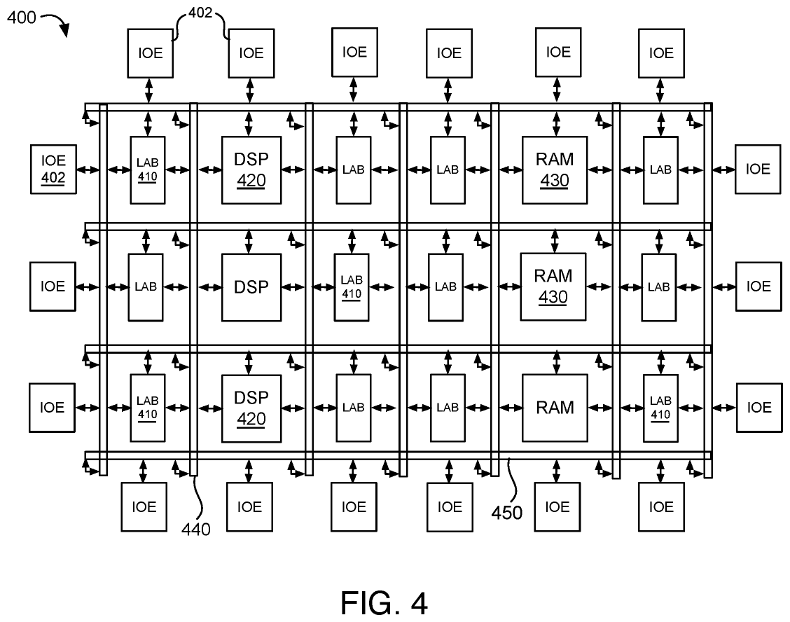

FIG. 4 is a diagram of another illustrative example of a configurable integrated circuit (IC) 400. Configurable IC 400 is an example of an IC as disclosed herein, such as IC 100. As shown in FIG. 4, the configurable integrated circuit 400 includes a two-dimensional array of functional blocks, including logic array blocks (LABs) 410 and other functional blocks, such as random access memory (RAM) blocks 430 and digital signal processing (DSP) blocks 420, for example. Functional blocks, such as LABs 410, may include smaller programmable regions (e.g., logic elements, configurable logic blocks, or adaptive logic modules) that receive input signals and perform custom functions on the input signals to produce output signals.

In addition, the configurable integrated circuit 400 may have input/output elements (IOEs) 402 for driving signals off of configurable integrated circuit 400 and for receiving signals from other devices. Input/output elements 402 may include parallel input/output circuitry, serial data transceiver circuitry, differential receiver and transmitter circuitry, or other circuitry used to connect one integrated circuit to another integrated circuit. As shown, input/output elements 402 may be located around the periphery of the IC. If desired, the configurable integrated circuit 400 may have input/output elements 402 arranged in different ways. For example, input/output elements 402 may form one or more columns of input/output elements that may be located anywhere on the configurable integrated circuit 400 (e.g., distributed evenly across the width of the configurable integrated circuit). If desired, input/output elements 402 may form one or more rows of input/output elements (e.g., distributed across the height of the configurable integrated circuit). Alternatively, input/output elements 402 may form islands of input/output elements that may be distributed over the surface of the configurable integrated circuit 400 or clustered in selected areas.

The configurable integrated circuit 400 may also include programmable interconnect circuitry in the form of vertical routing channels 440 (i.e., interconnects formed along a vertical axis of configurable integrated circuit 400) and horizontal routing channels 450 (i.e., interconnects formed along a horizontal axis of configurable integrated circuit 400), each routing channel including at least one track to route at least one wire.

Note that other routing topologies, besides the topology of the interconnect circuitry depicted in FIG. 4, may be used. For example, the routing topology may include wires that travel diagonally or that travel horizontally and vertically along different parts of their extent as well as wires that are perpendicular to the device plane in the case of three dimensional integrated circuits, and the driver of a wire may be located at a different point than one end of a wire. The routing topology may include global wires that span substantially all of configurable integrated circuit 400, fractional global wires such as wires that span part of configurable integrated circuit 400, staggered wires of a particular length, smaller local wires, or any other suitable interconnection resource arrangement.

Furthermore, it should be understood that examples disclosed herein may be implemented in any type of integrated circuit. If desired, the functional blocks of such an integrated circuit may be arranged in more levels or layers in which multiple functional blocks are interconnected to form still larger blocks. Other device arrangements may use functional blocks that are not arranged in rows and columns.

Configurable integrated circuit 400 may contain programmable memory elements. Memory elements may be loaded with configuration data (also called programming data) using input/output elements (IOEs) 402. Once loaded, the memory elements each provide a corresponding static control signal that controls the operation of an associated functional block (e.g., LABs 410, DSP 420, RAM 430, or input/output elements 402).

In a typical scenario, the outputs of the loaded memory elements are applied to the gates of field-effect transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory or programmable memory elements.

The programmable memory elements may be organized in a configuration memory array consisting of rows and columns. A data register that spans across all columns and an address register that spans across all rows may receive configuration data. The configuration data may be shifted onto the data register. When the appropriate address register is asserted, the data register writes the configuration data to the configuration memory elements of the row that was designated by the address register.

Configurable integrated circuit 400 can include configuration memory that is organized in sectors, whereby a sector may include the configuration RAM bits that specify the function and/or interconnections of the subcomponents and wires in or crossing that sector. Each sector may include separate data and address registers.

The configurable IC of FIG. 4 is merely one example of an IC that can be used with embodiments disclosed herein. The embodiments disclosed herein can be used with any suitable electronic integrated circuit or system. For example, the embodiments disclosed herein can be used with numerous types of electronic devices such as processor integrated circuits, central processing units, memory integrated circuits, graphics processing unit integrated circuits, application specific standard products (ASSPs), application specific integrated circuits (ASICs), and configurable logic integrated circuits. Examples of configurable logic integrated circuits include programmable arrays logic (PALs), programmable logic arrays (PLAs), field programmable logic arrays (FPGAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

It can be a significant undertaking to design and implement a desired (custom) logic circuit design in a configurable logic integrated circuit (IC). Logic designers therefore generally use logic design systems based on computer-aided-design (CAD) tools to assist them in designing circuits. A logic design system can help a logic designer design and test complex circuits for a system. When a design is complete, the logic design system can be used to generate configuration data in a bitstream for electrically programming the appropriate configurable logic IC.

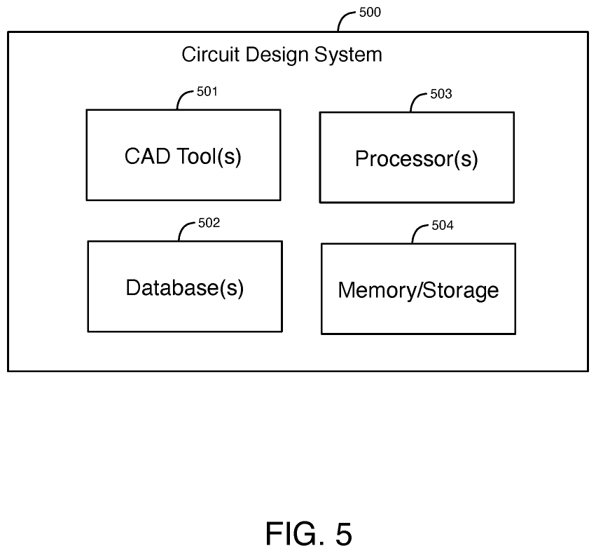

An illustrative circuit design system 500 in accordance with an embodiment is shown in FIG. 5. If desired, the circuit design system of FIG. 5 can be used in a logic design system. Circuit design system 500 can be implemented on integrated circuit design computing equipment. Circuit design system 500 can, for example, include one or more networked computer systems with processors, memory, mass storage, input/output devices, etc. System 500 can, for example, be based on one or more processors 503 such as personal computers, workstations, etc. The processor(s) 503 can be linked using a network (e.g., a local or wide area network). Memory in these computers or external memory and storage devices (collectively shown as memory/storage 504 in FIG. 5) can be used to store instructions and data.

Software-based components such as computer-aided design (CAD) tool(s) 501 and database(s) 502 reside on system 500. During operation, executable software such as the software of computer aided design tool(s) 501 runs on the processor(s) 503 of system 500. Database(s) 502 are used to store data for the operation of system 500. In general, software and data may be stored in non-transitory computer readable storage media (e.g., tangible computer readable storage media), such as memory/storage 504. The software code may sometimes be referred to as software, data, program instructions, instructions, or code. The non-transitory computer readable storage media may include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

Software stored on the non-transitory computer readable storage media may be executed on system 500. When the software of system 500 is installed, the storage of system 500 has instructions and data that cause the computing equipment in system 500 to execute various methods (processes). When performing these processes, the computing equipment is configured to implement the functions of circuit design system 500.

The computer aided design (CAD) tool(s) 501, some or all of which are sometimes referred to collectively as a CAD tool, a circuit design tool, or an electronic design automation (EDA) tool, may be provided by a single vendor or by multiple vendors. Tool(s) 501 may be provided as one or more suites of tools (e.g., a compiler suite for performing tasks associated with implementing a circuit design in a programmable IC) and/or as one or more separate software components (tools). Database(s) 502 may include one or more databases that are accessed only by a particular tool or tools and may include one or more shared databases. Shared databases may be accessed by multiple tools. For example, a first tool may store data for a second tool in a shared database. The second tool may access the shared database to retrieve the data stored by the first tool. This allows one tool to pass information to another tool. Tools may also pass information between each other without storing information in a shared database if desired.

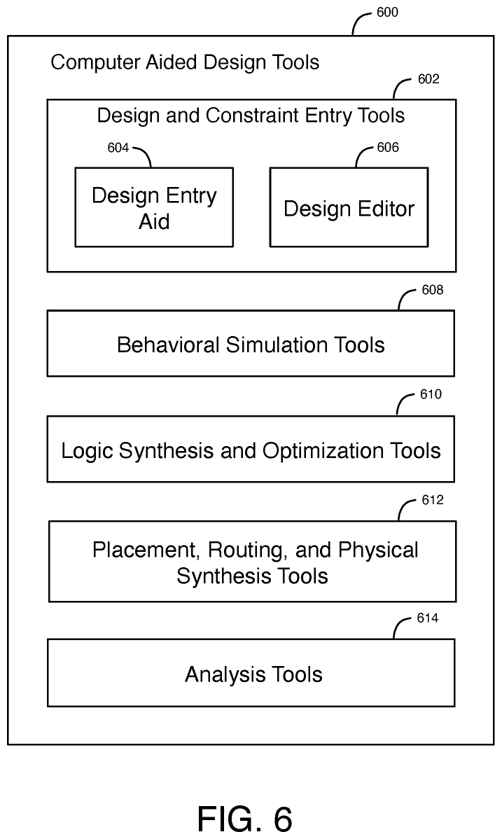

Illustrative computer aided design tools 600 that can be used in a circuit design system such as circuit design system 500 of FIG. 5 are shown in Figure (FIG. 6. The design process can start with the formulation of functional specifications of the circuit design (e.g., a functional or behavioral description of the circuit design). A circuit designer can specify the functional operation of a desired circuit design using design and constraint entry tools 602. Design and constraint entry tools 602 can include tools such as design and constraint entry aid 604 and design editor 606. Design and constraint entry aids such as aid 604 can be used to help a circuit designer locate a desired design from a library of existing circuit designs and can provide computer-aided assistance to the circuit designer for entering (specifying) the desired circuit design. Design and constraint entry tools 602 can allow a circuit designer to enter timing constraints for the desired circuit design through aid 604.

As an example, design and constraint entry aid 604 can be used to present screens of options for a user. The user can click on on-screen options to select whether the circuit being designed should have certain features. Design editor 606 can be used to enter a design (e.g., by entering lines of hardware description language code), can be used to edit a design obtained from a library (e.g., using a design and constraint entry aid), or can assist a user in selecting and editing appropriate prepackaged code/designs.

Design and constraint entry tools 602 can be used to allow a circuit designer to provide a desired circuit design using any suitable format. For example, design and constraint entry tools 602 can include tools that allow the circuit designer to enter a circuit design using truth tables. Truth tables can be specified using text files or timing diagrams and can be imported from a library. Truth table circuit design and constraint entry can be used for a portion of a large circuit or for an entire circuit.

As another example, design and constraint entry tools 602 can include a schematic capture tool. A schematic capture tool can allow the circuit designer to visually construct integrated circuit designs from constituent parts such as logic gates and groups of logic gates. Libraries of preexisting integrated circuit designs can be used to allow a desired portion of a design to be imported with the schematic capture tools.

If desired, design and constraint entry tools 602 can allow the circuit designer to provide a circuit design to the circuit design system 500 using a hardware description language such as Verilog hardware description language (Verilog HDL), Very High Speed Integrated Circuit Hardware Description Language (VHDL), SystemVerilog, or a higher-level circuit description language such as OpenCL or SystemC, just to name a few. The designer of the integrated circuit design can enter the circuit design by writing hardware description language code with editor 606. Blocks of code can be imported from user-maintained or commercial libraries if desired.

After the circuit design has been entered using design and constraint entry tools 602, behavioral simulation tools 608 can be used to simulate the functionality of the circuit design. If the functionality of the design is incomplete or incorrect, the circuit designer can make changes to the circuit design using design and constraint entry tools 602. The functional operation of the new circuit design can be verified using behavioral simulation tools 608 before synthesis operations have been performed using tools 610. Simulation tools such as behavioral simulation tools 608 can also be used at other stages in the design flow if desired (e.g., after logic synthesis). The output of the behavioral simulation tools 608 can be provided to the circuit designer in any suitable format (e.g., truth tables, timing diagrams, etc.).

After the functional operation of the circuit design has been determined to be satisfactory, logic synthesis and optimization tools 610 can generate a gate-level netlist of the circuit design, for example, using gates from a particular library pertaining to a targeted process supported by a foundry that has been selected to produce the integrated circuit. Alternatively, logic synthesis and optimization tools 610 can generate a gate-level netlist of the circuit design using gates of a targeted configurable IC (i.e., in the logic and interconnect resources of a particular configurable IC product or product family).

Logic synthesis and optimization tools 610 can optimize the circuit design by making appropriate selections of hardware to implement different logic functions in the circuit design based on the circuit design data and constraint data entered by the logic designer using tools 602. As an example, logic synthesis and optimization tools 610 can perform multi-level logic optimization and technology mapping based on the length of a combinational path between registers in the circuit design and corresponding timing constraints that were entered by the logic designer using tools 602.

After logic synthesis and optimization using tools 610, the circuit design system 500 can use tools such as placement, routing, and physical synthesis tools 612 to perform physical design steps (layout synthesis operations). Tools 612 can be used to determine where to place each gate of the gate-level netlist produced by tools 610. For example, if two counters interact with each other, tools 612 may locate these counters in adjacent regions to reduce interconnect delays or to satisfy timing requirements specifying the maximum permitted interconnect delay. Tools 612 create orderly and efficient implementations of circuit designs for any targeted integrated circuit (e.g., for a given configurable integrated circuit such as a field-programmable gate array (FPGA)).

Tools such as tools 610 and 612 can be part of a compiler suite (e.g., part of a suite of compiler tools provided by a programmable IC vendor). After an implementation of the desired circuit design has been generated using tools 612, the implementation of the design can be analyzed and tested using analysis tools 614. For example, analysis tools 614 can include timing analysis tools, power analysis tools, or formal verification tools, just to name few.

After satisfactory optimization operations have been completed using tools 600 and depending on the targeted integrated circuit technology, tools 600 can produce a mask-level layout description of the integrated circuit or configuration data for programming the configurable logic IC.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

Additional examples are now described. Example 1 is an integrated circuit comprising: a region of configurable logic circuits; and a configuration controller circuit that generates a first health condition report indicating a first health condition of the region before configuring the configurable logic circuits according to a circuit design, and wherein the configuration controller circuit generates a second health condition report indicating a second health condition of the region after configuring the configurable logic circuits according to the circuit design.

In Example 2, the integrated circuit of Example 1 may optionally include, wherein the configuration controller circuit compares the first health condition report to the second health condition report to determine if the circuit design caused any damage or degradation to the integrated circuit.

In Example 3, the integrated circuit of any one of Examples 1-2 may optionally include, wherein the configuration controller circuit generates an attestation of the first health condition report that comprises a timestamp indicating a time of generation of the first health condition report.

In Example 4, the integrated circuit of any one of Examples 1-3 may optionally include, wherein the configuration controller circuit generates each of the first health condition report and the second health condition report based on results of tests performed on the configurable logic circuits.

In Example 5, the integrated circuit of Example 4 may optionally include, wherein the configuration controller circuit performs the tests by providing test patterns to the configurable logic circuits and receiving outputs from the configurable logic circuits generated in response to the test patterns.

In Example 6, the integrated circuit of any one of Examples 1-5 may optionally include, wherein the configuration controller circuit de-configures the circuit design after the circuit design has completed a workload.

In Example 7, the integrated circuit of any one of Examples 1-6 may optionally include, wherein the configuration controller circuit generates an attestation of a bitstream used to configure the configurable logic circuits according to the circuit design.

In Example 8, the integrated circuit of any one of Examples 1-7 may optionally include, wherein the configuration controller circuit decrypts an encrypted bitstream of the circuit design to generate a decrypted bitstream and provides the decrypted bitstream to the region.

Example 9 is a method for assessing configurable logic circuits in a region of an integrated circuit, the method comprising: determining a first health of the configurable logic circuits in the region; configuring the configurable logic circuits in the region according to a circuit design after the first health is determined; and determining a second health of the configurable logic circuits in the region after the circuit design has been de-configured from the configurable logic circuits.

In Example 10, the method of Example 9 further comprises: comparing the first health to the second health to determine if the circuit design caused any damage or degradation to the configurable logic circuits.

In Example 11, the method of any one of Examples 9-10 may optionally include, wherein determining the first health of the configurable logic circuits comprises determining the first health of the configurable logic circuits by performing first tests of the configurable logic circuits and generating a first health report that comprises first results of the first tests using a configuration controller circuit in the integrated circuit.

In Example 12, the method of Example 11 may optionally include, wherein determining the second health of the configurable logic circuits comprises determining the second health of the configurable logic circuits by performing second tests of the configurable logic circuits and generating a second health report that comprises second results of the second tests using the configuration controller circuit.

In Example 13, the method of Example 12 further comprises: comparing the first health report to the second health report to determine if the circuit design caused any damage or degradation to the integrated circuit.

In Example 14, the method of any one of Examples 9-13 further comprises: de-configuring the circuit design from the configurable logic circuits after the circuit design has completed a workload.

In Example 15, the method of any one of Examples 9-14 further comprises: generating an attestation of a bitstream used to configure the configurable logic circuits according to the circuit design using a configuration controller circuit in the integrated circuit.

Example 16 is a non-transitory computer readable storage medium comprising computer readable instructions stored thereon for causing a computing system to: collect first health information of configurable logic circuits in a region of an integrated circuit to generate a first health report before the configurable logic circuits have been configured according to a circuit design; and collect second health information of the configurable logic circuits in the region to generate a second health report after the configurable logic circuits have been de-configured from the circuit design.

In Example 17, the non-transitory computer readable storage medium of Example 16 may optionally include, wherein the computer readable instructions further cause the computing system to compare the first health report to the second health report to determine how the circuit design changed operation of the configurable logic circuits.

In Example 18, the non-transitory computer readable storage medium of any one of Examples 16-17 may optionally include, wherein the computer readable instructions further cause the computing system to configure the configurable logic circuits in the region according to the circuit design after the first health report is generated using a configuration controller circuit in the integrated circuit.

In Example 19, the non-transitory computer readable storage medium of any one of Examples 16-18 may optionally include, wherein the computer readable instructions further cause the computing system to collect each of the first health information and the second health information by performing tests of the configurable logic circuits using test patterns and receiving results of the tests.

In Example 20, the non-transitory computer readable storage medium of any one of Examples 16-19 may optionally include, wherein the computer readable instructions further cause the computing system to generate an attestation of the first health report that comprises a timestamp indicating a time of generation of the first health report.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

1. An integrated circuit comprising:
a region of configurable logic circuits; and
a configuration controller circuit that generates a first health condition report indicating a first health condition of the region before configuring the configurable logic circuits according to a circuit design, and wherein the configuration controller circuit generates a second health condition report indicating a second health condition of the region after configuring the configurable logic circuits according to the circuit design.

2. The integrated circuit of claim 1, wherein the configuration controller circuit compares the first health condition report to the second health condition report to determine if the circuit design caused any damage or degradation to the integrated circuit.

3. The integrated circuit of claim 1, wherein the configuration controller circuit generates an attestation of the first health condition report that comprises a timestamp indicating a time of generation of the first health condition report.

4. The integrated circuit of claim 1, wherein the configuration controller circuit generates each of the first health condition report and the second health condition report based on results of tests performed on the configurable logic circuits.

5. The integrated circuit of claim 4, wherein the configuration controller circuit performs the tests by providing test patterns to the configurable logic circuits and receiving outputs from the configurable logic circuits generated in response to the test patterns.

6. The integrated circuit of claim 1, wherein the configuration controller circuit de-configures the circuit design after the circuit design has completed a workload.

7. The integrated circuit of claim 1, wherein the configuration controller circuit generates an attestation of a bitstream used to configure the configurable logic circuits according to the circuit design.

8. The integrated circuit of claim 1, wherein the configuration controller circuit decrypts an encrypted bitstream of the circuit design to generate a decrypted bitstream and provides the decrypted bitstream to the region.

9. A method for assessing configurable logic circuits in a region of an integrated circuit, the method comprising:
determining a first health of the configurable logic circuits in the region;
configuring the configurable logic circuits in the region according to a circuit design after the first health is determined; and
determining a second health of the configurable logic circuits in the region after the circuit design has been de-configured from the configurable logic circuits.

10. The method of claim 9 further comprising:
comparing the first health to the second health to determine if the circuit design caused any damage or degradation to the configurable logic circuits.

11. The method of claim 9, wherein determining the first health of the configurable logic circuits comprises determining the first health of the configurable logic circuits by performing first tests of the configurable logic circuits and generating a first health report that comprises first results of the first tests using a configuration controller circuit in the integrated circuit.

12. The method of claim 11, wherein determining the second health of the configurable logic circuits comprises determining the second health of the configurable logic circuits by performing second tests of the configurable logic circuits and generating a second health report that comprises second results of the second tests using the configuration controller circuit.

13. The method of claim 12 further comprising:
comparing the first health report to the second health report to determine if the circuit design caused any damage or degradation to the integrated circuit.

14. The method of claim 9 further comprising:
de-configuring the circuit design from the configurable logic circuits after the circuit design has completed a workload.

15. The method of claim 9 further comprising:
generating an attestation of a bitstream used to configure the configurable logic circuits according to the circuit design using a configuration controller circuit in the integrated circuit.

16. A non-transitory computer readable storage medium comprising computer readable instructions stored thereon for causing a computing system to:
collect first health information of configurable logic circuits in a region of an integrated circuit to generate a first health report before the configurable logic circuits have been configured according to a circuit design; and
collect second health information of the configurable logic circuits in the region to generate a second health report after the configurable logic circuits have been de-configured from the circuit design.

17. The non-transitory computer readable storage medium of claim 16, wherein the computer readable instructions further cause the computing system to compare the first health report to the second health report to determine how the circuit design changed operation of the configurable logic circuits.

18. The non-transitory computer readable storage medium of claim 16, wherein the computer readable instructions further cause the computing system to configure the configurable logic circuits in the region according to the circuit design after the first health report is generated using a configuration controller circuit in the integrated circuit.

19. The non-transitory computer readable storage medium of claim 16, wherein the computer readable instructions further cause the computing system to collect each of the first health information and the second health information by performing tests of the configurable logic circuits using test patterns and receiving results of the tests.

20. The non-transitory computer readable storage medium of claim 16, wherein the computer readable instructions further cause the computing system to generate an attestation of the first health report that comprises a timestamp indicating a time of generation of the first health report.
